(19) United States
(12) Patent Application Publication
(10) Pub. No.: US 2004/0189155 A1
(43) Pub. Date: Sep. 30, 2004

(54) Ultrasonic transducer and ultrasonic motor

(75) Inventor: Tomoki Funakubo, Tokyo (JP)

Correspondence Address: SCULLY SCOTT MURPHY & PRESSER, PC, 400 GARDEN CITY PLAZA, GARDEN CITY, NY, 11530

(73) Assignee: OLYMPUS CORPORATION, TOKYO (JP)

(21) Appl. No.: 10/801,444

(22) Filed: Mar. 16, 2004

(30) Foreign Application Priority Data
Mar. 27, 2003 (JP) 2003-088955

(51) Int. Cl. H01L 41/083

(52) U.S. Cl. 310/366

(57) ABSTRACT

An ultrasonic transducer includes a first outer-electrode group and includes a first outer-electrode group and a second outer-electrode group, in which the piezoelectric elements and the internal electrodes is alternately layered respectively, and that are connected to the corresponding internal electrodes. Upon alternating voltage being applied to the first outer-electrode group and/or the second outer-electrode group, a primary resonant mode and a secondary resonant mode are simultaneously excited to generate ultrasonic elliptical vibration. The ultrasonic transducer further includes conducting films for connecting outer electrodes, formed closely contacting with the surface of the ultrasonic transducer, so as to electrically connecting predetermined outer electrodes in the first outer-electrode group to predetermined outer electrodes in the second outer-electrode group.

This application claims benefit of Japanese Application No. 2003-88955 filed in Japan on Mar. 27, 2003, the contents of which are incorporated by this reference.

### BACKGROUND OF THE INVENTION

1. Field of the Invention

The present invention relates to an ultrasonic transducer having a structure in which internal electrodes and piezoelectric elements are layered and to an ultrasonic motor using the ultrasonic transducer.

2. Description of the Related Art

Ultrasonic motors have drawn attention in recent years as new motors which can be used in place of electromagnetic motors. The ultrasonic motors have the following advantages, compared with known electromagnetic motors.

(1) Low speed and high torque yielded without using gears

(2) High maintaining power of driving force

(3) Long stroke and high resolution

(4) Quiet

(5) No magnetic noise produced and no noise influence

Ultrasonic motor having such advantages include an ultrasonic motor disclosed in Japanese Unexamined Patent Application Publication No. 7-163162, which is filed by the applicant.

The known ultrasonic motor disclosed in Japanese Unexamined Patent Application Publication No. 7-163162 will now be described with reference to FIGS. 11 and 12.

FIGS. 11 and 12 illustrate a structure example of the known ultrasonic motor disclosed in the above publication. FIG. 11 is an essential-part exploded perspective view showing in detail the basic parts of an ultrasonic transducer 60 used in the ultrasonic motor. FIG. 12 is a front view of the ultrasonic transducer 60 used in the ultrasonic motor.

The structure of the ultrasonic transducer 60 will now be described.

The known ultrasonic motor disclosed in the above publication uses the ultrasonic transducer 60 in FIG. 12, in which a plurality of thin rectangular piezoelectric plates 51 are layered, as shown in FIG. 11. A first piezoelectric plate has a pair of an upper internal electrode 57c and a lower internal electrode 57d printed thereon. A second piezoelectric plate has a pair of an upper internal electrode 57e and a lower internal electrode 57f printed thereon. The ultrasonic transducer 60 has a structure in which the first and second piezoelectric plates are alternately layered.

The ultrasonic transducer 60 has piezoelectric plates 52 that serve as insulators and that do not undergo electrode treatment. The piezoelectric plates 52 are inserted at the head of the layer including the first and second piezoelectric plates, at the center thereof, and at the tail thereof. The central piezoelectric plate 52 has a hole 55 at a node substantially common to longitudinal resonance and flexural resonance.

The upper internal electrode 57c and the lower internal electrode 57d extend toward as far as the front side of the ultrasonic transducer 60. The internal electrode 57e and the internal electrode 57f extend toward as far as the rear side of the ultrasonic transducer 60. The piezoelectric plates 51, each having the electrodes printed on a PZT green sheet, are burned after being positioned and layered.

Outer electrodes 54 are provided on places where the internal electrodes in the ultrasonic transducer 60 are exposed outside (the outer electrodes provided on four places on the front face serve as positive electrodes and the outer electrodes provided on four places on the rear face serve as negative electrodes), as shown in FIG. 12.

By connecting the outer electrode 54 at the upper left on the front face to the outer electrode 54 at the lower right thereon by using a lead wire, an A-phase outer electrode (positive electrode) is formed. By connecting the outer electrode 54 at the upper right on the front face to the outer electrode 54 at the lower left thereon by using another lead wire, a B-phase outer electrode (positive electrode) is formed. The four outer electrodes 54 on the rear face of the ultrasonic transducer 60 are wired in the same manner to form an A-phase outer electrode (negative electrode) and a B-phase outer electrode (negative electrode), although not shown. Applying DC voltage to the A-phase and B-phase outer electrodes polarizes the outer electrodes 54.

Frictional members 58 are bonded to positions where the flexural resonance beneath the ultrasonic transducer 60 measures substantially maximal amplitude.

Upon alternating voltage offset by π/2 phase being applied to the A-phase and B-phase outer electrodes on the ultrasonic transducer 60 having the structure described above, large elliptical vibration is excited at the positions of the frictional members 58.

In the ultrasonic motor using the ultrasonic transducer 60, a pin 59 for fixing the ultrasonic transducer 60 is inserted through the small through hole 55 at the center of the ultrasonic transducer 60 and is bonded to the through hole 55. Pressing means that is engaged with the pin 59 to press the ultrasonic transducer 60 downward in FIG. 12 and a driven body that is in contact with the frictional members 58 on the ultrasonic transducer 60 and that moves with respect to the frictional members 58 are provided, although not shown, in order to operate the ultrasonic motor. The driven body is held by a linear guide.

In the ultrasonic motor having the structure described above, applying alternating voltage offset by π/2 phase to the A-phase and B-phase outer electrodes on the ultrasonic transducer 60 in FIG. 12 for exciting the primary longitudinal resonance and the secondary flexural resonance to generate elliptical vibration at the positions of the frictional members 58 can horizontally move the driven body (not shown).

### SUMMARY OF THE INVENTION

An ultrasonic transducer of the present invention includes a first outer-electrode group and a second outer-electrode group, in which the piezoelectric elements and the internal electrodes is alternately layered respectively, and that are connected to the corresponding internal electrodes. Upon alternating voltage being applied to the first outer-electrode group and/or the second outer-electrode group, a primary resonant mode and a secondary resonant mode are simultaneously excited to generate ultrasonic elliptical vibration. The ultrasonic transducer further includes conducting films for connecting outer electrodes, formed closely contacting with the surface of the ultrasonic transducer, so as to electrically connecting predetermined outer electrodes in the first outer-electrode group to predetermined outer electrodes in the second outer-electrode group.

These objects and advantages of the present invention will become further apparent from the following detailed explanation.

### BRIEF DESCRIPTION OF THE DRAWINGS

FIG. 1A is a top view of the ultrasonic transducer; FIG. 1A to FIG. 6A relate to a first embodiment of the present invention, schematically showing the configurative appearances of an ultrasonic transducer mounted in an ultrasonic motor.

FIG. 1B is a front view of the ultrasonic transducer in FIG. 1A;

FIG. 1C is a left-side view of the ultrasonic transducer in FIG. 1A;

FIG. 1D is a rear view of the ultrasonic transducer in FIG. 1A;

FIG. 1E is a right-side view of the ultrasonic transducer in FIG. 1A;

FIG. 1F is a bottom view of the ultrasonic transducer in FIG. 1A;

FIG. 2 is an essential-part exploded perspective view showing in detail the basic parts of the ultrasonic transducer in FIGS. 1A to 1F;

FIG. 3A is a perspective view showing a longitudinal resonant state of the ultrasonic transducer of the first embodiment;

FIG. 3B is a perspective view showing a flexural resonant state of the ultrasonic transducer of the first embodiment;

FIG. 4A illustrates in detail the structure and the basic operation of the ultrasonic transducer of the first embodiment, and is a diagram illustrating ultrasonic elliptical vibration having a large amplitude has occurred;

FIG. 4B is a front view of the ultrasonic transducer having two frictional members beneath the bottom face;

FIG. 4C is a front view of the ultrasonic transducer having two frictional members at the both ends beneath the bottom face and upper top face respectively;

FIG. 4D is a front view of the ultrasonic transducer having one frictional member at the center of a side face;

FIG. 5A illustrates an excitation action occurring near a frictional member of the ultrasonic transducer of the first embodiment, and is a diagram illustrating that the phase of an alternating voltage applied to an A phase is behind the phase of an alternating voltage applied to a B phase by π/2;

FIG. 5B is a diagram illustrating that the phase of an alternating voltage applied to the A phase is ahead of the phase of an alternating voltage applied to the B phase by π/2;

FIG. 6A illustrates the basic structure of the ultrasonic motor using the ultrasonic transducer of the first embodiment, and is a front view of the ultrasonic motor;

FIG. 6B is a side view of the ultrasonic motor in FIG. 6A;

FIG. 7 illustrates an ultrasonic transducer and an ultrasonic motor using the ultrasonic transducer according to a second embodiment of the present invention, and is an essential-part exploded perspective view showing in detail the structure of internal electrodes of the ultrasonic transducer mounted in the ultrasonic motor;

FIG. 8A is a front view of the ultrasonic transducer of the second embodiment, schematically illustrating the configurative appearance of the ultrasonic transducer mounted in the ultrasonic motor;

FIG. 8B is a top view of the ultrasonic transducer in FIG. 8A;

FIG. 8C is a rear view of the ultrasonic transducer in FIG. 8A;

FIG. 8D is a bottom view of the ultrasonic transducer in FIG. 8A;

FIG. 9 is an essential-part exploded perspective view showing in detail the structure of internal electrodes of the ultrasonic transducer mounted in the ultrasonic motor, illustrating a third embodiment of the present invention of an ultrasonic transducer and an ultrasonic motor using the ultrasonic transducer;

FIG. 10A is a front view of the ultrasonic transducer of the third embodiment, schematically illustrating the configurative appearance of the ultrasonic transducer mounted in the ultrasonic motor;

FIG. 10B is a rear view of the ultrasonic transducer in FIG. 10A;

FIG. 10C is a left-side view of the ultrasonic transducer in FIG. 10A;

FIG. 10D is a right-side view of the ultrasonic transducer in FIG. 10A;

FIG. 11 is an essential-part exploded perspective view showing in detail the basic part of a known ultrasonic transducer used in an ultrasonic motor; and

FIG. 12 is a front view of the known ultrasonic transducer in FIG. 11.

### DETAILED DESCRIPTION OF THE PREFERRED EMBODIMENTS

Embodiments of the present invention will be described below with reference to the drawings.

### First Embodiment

(Structure)

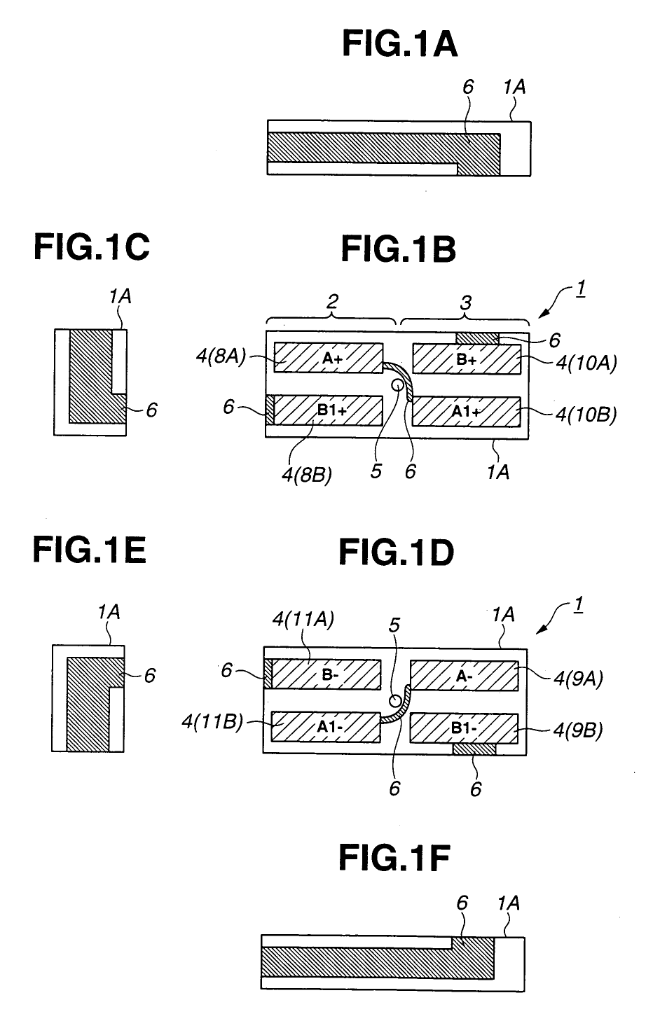

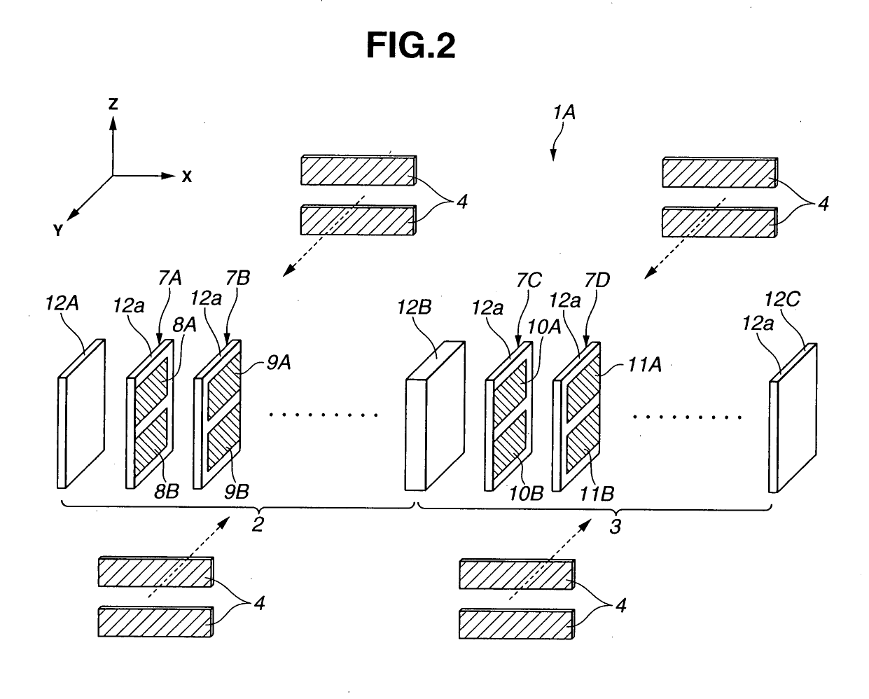

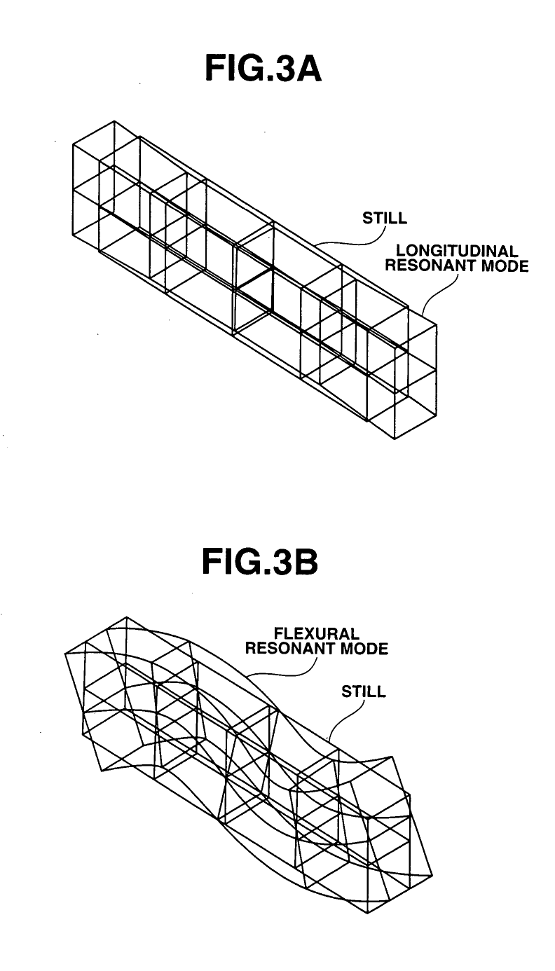

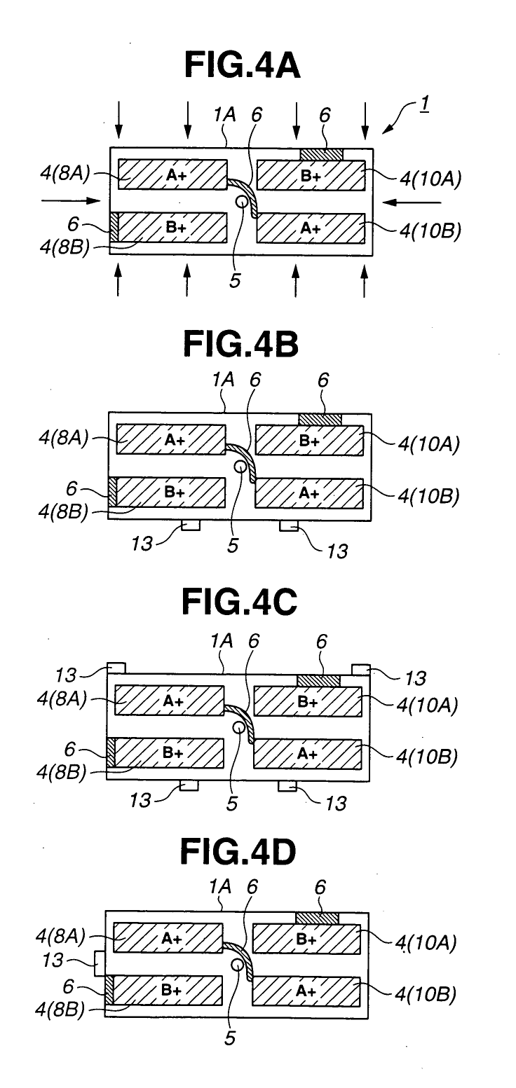

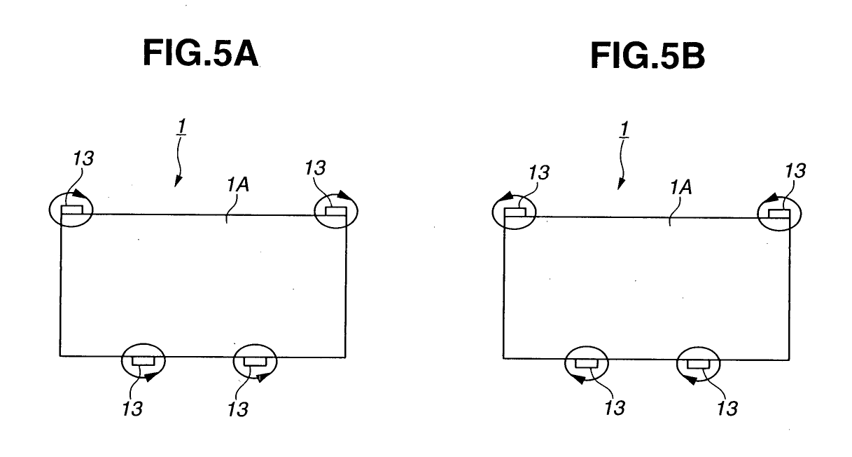

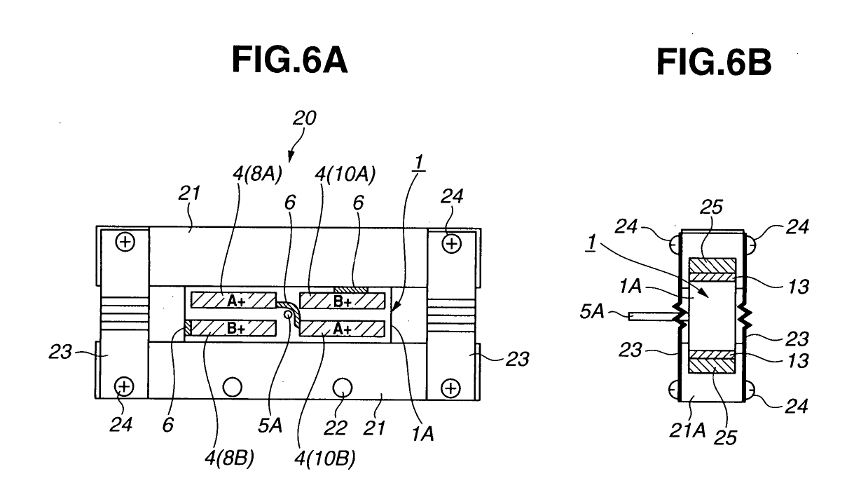

An ultrasonic transducer 1 according to a first embodiment of the present invention and an ultrasonic motor 20 using the ultrasonic transducer 1 will now be described with reference to FIGS. 1A to 6B. FIGS. 1A to IF are diagrams schematically showing the configurative appearances of the ultrasonic transducer 1 mounted in the ultrasonic motor 20; FIG. 1A is a top view of the ultrasonic transducer 1, FIG. 1B is a front view of the ultrasonic transducer 1, FIG. 1C is a left-side view of the ultrasonic transducer 1, FIG. 1D is a rear view of the ultrasonic transducer 1, FIG. 1E is a right-side view of the ultrasonic transducer 1, and FIG. 1F is a bottom view of the ultrasonic transducer 1. FIG. 2 is an essential-part exploded perspective view showing in detail the basic parts of the ultrasonic transducer 1 in FIG. 1A. FIG. 3 is a perspective view showing the operating state of the ultrasonic transducer 1 of the first embodiment; FIG. 3A illustrates a longitudinal resonant state and FIG. 3B illustrates a flexural resonant state. FIGS. 4A to 4D illustrate in detail the structure and the basic operation of the ultrasonic transducer 1 of the first embodiment; FIG. 4A is a diagram illustrating ultrasonic elliptical vibration having a large amplitude has occurred, FIG. 4B is a front view of the ultrasonic transducer 1 having two frictional members 13 beneath the bottom face, FIG. 4C is a front view of the ultrasonic transducer 1 having two frictional members 13 at the both ends beneath the bottom face and the top face respectively, and FIG. 4D is a front view of the ultrasonic transducer 1 having one frictional member 13 at the center of a side face. FIGS. 5A and 5B illustrate an excitation action occurring near a frictional member of the ultrasonic transducer 1 of the first embodiment; FIG. 5A is a diagram illustrating the phase of an alternating voltage applied to an A phase is behind the phase of an alternating voltage applied to a B phase by π/2 and FIG. 5B is a diagram illustrating the phase of an alternating voltage applied to the A phase is ahead of the phase of an alternating voltage applied to the B phase by π/2. FIGS. 6A and 6B illustrate the basic structure of the ultrasonic motor 20 using the ultrasonic transducer 1 of the first embodiment; FIG. 6A is a front view of the ultrasonic motor 20 and FIG. 6B is a side view of the ultrasonic motor 20.

The structure of the ultrasonic transducer 1 mounted in the ultrasonic motor 20 according to the first embodiment will now be described in detail with reference to FIGS. 1A to 1F and FIG. 2.

The ultrasonic transducer 1 of the first embodiment is a layered ultrasonic transducer, as shown in FIG. 2, and mainly includes a prismatic layered product 1A having a substantially rectangular cross section.

Referring to FIGS. 1B and 1D, the prismatic layered product 1A includes a first layered part 2 constituting a substantially left-half of the prismatic layered product, a second layered part 3 constituting a substantially right-half of the prismatic layered product, outer electrodes 4 provided at predetermined positions on the front face and the rear face of the first layered part 2 and the second layered part 3, and conducting films 6 for connecting outer electrodes, which characterize the first embodiment of the present invention.

According to the first embodiment, the prismatic layered product 1A measures, for example, 10 mm width by 2.4 mm height by 2 mm depth.

The structure of internal electrodes of the ultrasonic transducer 1 will now be described in detail with reference to FIG. 2. In the prismatic layered product 1A of the ultrasonic transducer 1, there are provided three insulative piezoelectric sheets 12A to 12C, which serve as insulators and are piezoelectrically inactive because of no electrode treatment. A plurality of rectangular piezoelectric sheets 7A and 7B, which are sandwiched between the insulative piezoelectric sheet 12A and the insulative piezoelectric sheet 12B to be alternately layered and undergone through internal-electrode treatment, constitute the first layered part 2; and a plurality of rectangular piezoelectric sheets 7C and 7D, which are sandwiched between the insulative piezoelectric sheet 12B and the insulative piezoelectric sheet 12C to be alternately layered and undergone through internal-electrode treatment, constitute the second layered part 3.

Specifically, alternately layering the two kinds of piezoelectric sheets 7A and 7B so as to be sandwiched between the insulative piezoelectric sheet 12A at the leftmost side of the prismatic layered product 1A and the insulative piezoelectric sheet 12B at the center of the prismatic layered product 1A constitutes the first layered part 2. Alternately layering the two kinds of piezoelectric sheets 7C and 7D so as to be sandwiched between the insulative piezoelectric sheet 12B at the center of the prismatic layered product 1A and the insulative piezoelectric sheet 12C at the rightmost side of the prismatic layered product 1A constitutes the second layered part 3. Although these insulative piezoelectric sheets 12A to 12C are not necessarily required, the rightmost insulative piezoelectric sheet 12C is desirably provided in order to prevent the internal electrodes from being exposed outside at the rightmost edge of the ultrasonic transducer 1.

The first layered part 2 has a structure in which the piezoelectric sheets 7A, each having first internal electrodes 8A and 8B formed thereon, and the piezoelectric sheets 7B, each having second internal electrodes 9A and 9B formed thereon, are alternately layered.

The second layered part 3 has a structure in which the piezoelectric sheets 7C, each having third internal electrodes 10A and 10B formed thereon, and the piezoelectric sheets 7D, each having fourth internal electrodes 11A and 11B formed thereon, are alternately layered.

In the first layered part 2, the piezoelectric sheet 7A is constructed such that the first internal electrode is divided substantially in half on a piezoelectric-sheet part 12a and so as to have areas to be connected to the outer electrodes (for an A-phase outer electrode (A+) and for a B-phase outer electrode (B1+)) at the corresponding edges of the first internal electrodes 8A and 8B formed by the division.

The piezoelectric sheet 7B is formed such that the second internal electrode is divided substantially in half on a piezoelectric-sheet part 12a and so as to have areas to be connected to the outer electrodes (for an A-phase outer electrode (A−) and for a B-phase outer electrode (B1−)) at the corresponding edges of the second internal electrodes 9A and 9B formed by the division.

In the second layered part 3, the piezoelectric sheet 7C is formed such that the third internal electrode is divided substantially in half on a piezoelectric-sheet part 12a and so as to have areas to be connected to the outer electrodes (for a B-phase outer electrode (B+) and for an A-phase outer electrode (A1+)) at the corresponding edges of the third internal electrodes 10A and 10B formed by the division.

The piezoelectric sheet 7D is formed such that the fourth internal electrode is divided substantially in half on a piezoelectric-sheet part 12a and so as to have areas to be connected to the outer electrodes (for a B-phase outer electrode (B−) and for an A-phase outer electrode (A1−)) at the corresponding edges of the fourth internal electrodes 11A and 11B formed by the division.

According to the first embodiment, the piezoelectric sheets 7A to 7D each measure, for example, 2.4 mm height by 2 mm depth by 80 μm thickness. The insulative piezoelectric sheets 12A and 12C each measure 2.4 mm height by 2 mm depth by 80 μm thickness. However, the central insulative piezoelectric sheet 12B has a thickness of 500 μm.

Although the piezoelectric sheets 7A to 7D and the piezoelectric-sheet parts 12a according to the first embodiment are made of lead zirconate titanate (PZT) ceramics, any piezoelectric material may be used to form the piezoelectric sheets and the piezoelectric-sheet parts. A hard material having a high mechanical quality factor (Qm), for example, having a Qm of about 2000, is selected in the first embodiment.

Referring to FIG. 2, on the piezoelectric sheet 7A, the first internal electrode is divided substantially in half with an insulating gap of around 0.4 mm provided in the Y direction, constituting the first internal electrodes 8A and 8B. On the piezoelectric sheet 7C, the third internal electrode is divided in half with an insulating gap of around 0.4 mm provided in the Y direction, constituting the third internal electrodes 10A and 10B. The first internal electrodes 8A and 8B and the third internal electrodes 10A and 10B each have an insulating gap of around 0.4 mm along the edges of the piezoelectric-sheet part 12a. However, as described above, the first internal electrodes 8A and 8B and the third internal electrodes 10A and 10B extend toward the proximal end of the ultrasonic transducer 1 where the first and third internal electrodes are in contact with the corresponding outer electrodes 4.

On the piezoelectric sheet 7B, the second internal electrode is also divided in half with an insulating gap of around 0.4 mm provided in the Y direction, constituting the second internal electrodes 9A and 9B. On the piezoelectric sheet 7D, the fourth internal electrode is also divided in half with an insulating gap of around 0.4 mm provided in the Y direction, constituting the fourth internal electrodes 11A and 11B. The second internal electrodes 9A and 9B and the fourth internal electrodes 11A and 11B each have an insulating gap of around 0.4 mm along the edges of the piezoelectric-sheet part 12a. However, the second internal electrodes 9A and 9B and the fourth internal electrodes 11A and 11B extend toward the distal end of the ultrasonic transducer 1 where the second and fourth internal electrodes are in contact with the corresponding outer electrodes 4.

Although the first to fourth internal electrodes are formed of an alloy of silver and palladium in the first embodiment, they may be made of silver, nickel, platinum, or gold. The first to fourth internal electrodes each have a thickness of around 4 μm.

As shown in FIG. 2, the outer electrodes 4 are provided at the portions where the first to fourth internal electrodes 8A to 11B in the prismatic layered product 1A are exposed outside, that is, at four portions on the front face and at four portions on the rear face.

The configurative appearances of the ultrasonic transducer 1 of the first embodiment will now be described in detail with reference to FIGS. 1A to 1F.

The ultrasonic transducer 1 of the first embodiment has the outer electrodes 4 at the four portions on the front face where the first internal electrodes 8A and 8B and the third internal electrodes 10A and 10B are exposed outside, as shown in FIG. 1B.

The conducting films 6 for connecting outer electrodes are used, in place of lead wires, which have been conventionally used, to connect the outer electrodes 4 to each other in the first embodiment.

Specifically, as shown in FIG. 1B, the outer electrode A+ is electrically connected to the outer electrode A1+ by using one conducting films 6 for connecting outer electrodes. Another conducting film 6 for connecting outer electrodes is connected to part of the B-phase outer electrode B+ and extends toward the top of the ultrasonic transducer 1. On the top face of the ultrasonic transducer 1, as shown in FIG. 1A, the conducting film 6 extends toward the left-side edge on the top face of the ultrasonic transducer 1. On the left-side face of the ultrasonic transducer 1, as shown in FIG. 1C, the conducting film 6 extends downward. The conducting film 6 on the left-side face is eventually connected to the outer electrode B1+.

In the meantime, the positive outer electrodes 4 are provided on the front face of the ultrasonic transducer 1, negative outer electrodes 4 corresponding to these positive outer electrodes 4 are provided on the rear face of the ultrasonic transducer 1, as shown in FIG. 1D. Of these negative outer electrodes 4, the outer electrodes 4 are electrically connected to the outer electrodes that are diagonally positioned by using the corresponding conducting films 6 for connecting outer electrodes, as shown in FIG. 1D.

Specifically, the outer electrode A− is electrically connected to the outer electrode A1− by using one conducting films 6 for connecting outer electrodes. Another conducting film 6 for connecting outer electrodes is connected to part of the outer electrode B1− and extends toward the bottom of the ultrasonic transducer 1. Beneath the bottom face of the ultrasonic transducer 1, as shown in FIG. 1F, the conducting film 6 extends toward the left-side edge on the bottom face of the ultrasonic transducer 1. On the right-side face of the ultrasonic transducer 1, as shown in FIG. 1E, the conducting film 6 extends upward. The conducting film 6 on the right-side face is eventually connected to the B-phase outer electrode B−.

Although the outer electrodes 4 and the conducting films 6 for connecting outer electrodes are formed of silver in the first embodiment, they may be made of an alloy of silver and palladium, an alloy of silver and platinum, or platinum.

The outer electrodes 4 and the conducting films 6 for connecting outer electrodes each have a thickness of 10 μm to 30 μm.

Lead wires are fixed with solder, or a flexible substrate having electrodes is electrically connected, to the A-phase (+), A-phase (−), B-phase (+), or B-phase (−) outer electrodes or to the conducting films 6 for connecting outer electrodes, for applying alternating voltage to drive the ultrasonic transducer 1, although not shown. As described below, a hole 5 in which a pin 5A (refer to FIGS. 6A and 6B) for fixing the ultrasonic transducer 1 is mounted is provided at the approximate center of the ultrasonic transducer 1, that is, at a node common to longitudinal resonance and flexural resonance.

The manufacturing process of the ultrasonic transducer 1 according to the first embodiment will now be described.

First, PZT temporarily sintered powder is mixed with binder to produce slurry. The slurry is casted into a film by using a doctor blade method to manufacture on the film the two kinds of piezoelectric sheets (also referred to as green sheets), that is, the insulative piezoelectric sheets 12A to 12C and the piezoelectric-sheet parts 12a of the piezoelectric sheets 7A to 7D.

The insulative piezoelectric sheets 12A to 12C and the piezoelectric-sheet parts 12a of the piezoelectric sheets 7A to 7D are dried and exfoliated from the film.

Next, the piezoelectric sheet 7A is formed by having material of the internal electrodes printed on a piezoelectric-sheet part-12a by using a mask having the pattern of the first internal electrodes (8A and 8B). The same process forms the piezoelectric sheet 7C having the third internal electrodes (10A and 10B) printed.

The piezoelectric sheet 7B is formed by having the material of the internal electrodes printed on another. piezoelectric-sheet part 12a by using a mask having the pattern of the second internal electrodes (9A and 9B). The same process forms the piezoelectric sheet 7D having the fourth internal electrodes (11A and 11B) printed.

As described above, the two kinds of piezoelectric sheets, that is, the piezoelectric sheets, each having the pattern for the piezoelectric sheet 7A and 7C, and the piezoelectric sheets, each having the patterns for the piezoelectric sheets 7B and 7D, are formed in the first embodiment.

The insulative piezoelectric sheets 12A to 12C are prepared. The two kinds of piezoelectric sheets (the piezoelectric sheets 7A and 7C and the piezoelectric sheets 7B and 7D) are accurately positioned being layered between the insulative piezoelectric sheets 12A to 12C in the layered structure shown in FIG. 2.

These layered piezoelectric sheets (the prismatic layered product 1A) are burned at a temperature of 1200° C. after thermocompression. The piezoelectric sheets are, then, cut out into a predetermined shape (for example, the shape shown in FIGS. 1A to 1F).

The exposed portions of the first to fourth internal electrodes 8A to 11B in the prismatic layered product 1A are plated with silver to form the outer electrodes 4.

The conducting films 6 for connecting outer electrodes are formed in the same manner as in the conducting mode described with reference to FIGS. 1A to 1F in the first embodiment.

Finally, upon DC high voltage being applied to the A-phase and B-phase outer electrodes 4 (8A to 11B), the outer electrodes 4 are polarized.

The ultrasonic transducer 1 of the first embodiment is manufactured in the manner described above.

(Operation)

The operation of the ultrasonic transducer 1 having the structure described above will now be described in detail with reference to FIGS. 1A to 5B.

It is assumed that the lead wires (or the flexible substrate) are connected by soldering to the lead terminal of each of the outer electrodes 4, although not shown, and that the lead wires (or the flexible substrate) are electrically connected to a driving power supply that acts as driving power-supply means for the ultrasonic transducer 1, although not shown.

Upon alternating voltage having a frequency of around 160 KHz in phase being applied to the A-phase and B-phase outer electrodes of the ultrasonic transducer 1 in FIG. 1B, primary longitudinal resonance in the ultrasonic transducer 1 is excited. Upon alternating voltage having a frequency of around 160 KHz in opposite phase being applied to the A-phase and B-phase outer electrodes, secondary flexural resonance in the ultrasonic transducer 1 is excited.

As a result of computer analysis of the resonance by using a finite element method, the longitudinal resonance state in FIG. 3A and the flexural resonance state in FIG. 3B have been predicted and as a result of a vibration measurement, the prediction has been proved.

The ultrasonic transducer 1 is designed such that the resonant frequency of the secondary flexural resonance is lower than the resonant frequency of the primary longitudinal resonance by around several percent (desirably, around three percent). Such a design drastically increases the output characteristics of the ultrasonic motor 20 described below.

Upon alternating voltage having a frequency of 160 KHz offset by π/2 phase being applied to the A-phase and B-phase outer electrodes of the ultrasonic transducer 1 in FIG. 1B, ultrasonic elliptical vibration having a large amplitude at a position indicated by an arrow in FIG. 4A is generated. According to the first embodiment, the longitudinal piezoelectric effect is used to excite the primary longitudinal resonance and the secondary flexural resonance.

When the ultrasonic transducer is used in the ultrasonic motor 20, the frictional members 13 are joined to positions where the ultrasonic elliptical vibration is generated.

FIG. 4B shows a structure example in which two frictional members 13 are bonded to positions that are respectively apart by about 3 mm from both ends beneath the bottom face of the ultrasonic transducer 1 (the prismatic layered product 1A).

The frictional members 13 are formed of resin including dispersed alumina. According to the first embodiment, the frictional members 13 each measure 1 mm width by 0.5 mm height by 1.8 mm depth, for example, as shown in FIGS. 4A to 4D.

The hole 5 for pressing and holding the ultrasonic transducer 1 is provided at the center of the ultrasonic transducer 1, namely at the node common to the primary longitudinal resonance and the secondary flexural resonance in the first embodiment. The pin 5A (refer to FIGS. 6A and 6B) for fixing the ultrasonic transducer 1 is gone through the hole 5 to press and hold the ultrasonic transducer 1.

FIG. 4C is another structure example in which two frictional members 13 are bonded to positions that are respectively apart by about 3 mm from both ends beneath the bottom face of the ultrasonic transducer 1 (the prismatic layered product 1A) and two frictional members 13 are bonded to both ends on the top face of the ultrasonic transducer 1 (prismatic layered product 1A).

In the case in FIG. 4C, as shown in FIGS. 5A and 5B, the pair of frictional members 13 on the top face of the prismatic layered product 1A generates the elliptical vibration in a direction counter to the direction of the elliptical vibration generated by the pair of the frictional members 13 beneath the bottom face of the prismatic layered product 1A, so that a pair of guides 21 described below are provided on and beneath the frictional members 13 to constitute an automotive motor in which the ultrasonic transducer 1 itself moves. A hole 5 in which a pin 5A for transmitting a driving force from the ultrasonic transducer 1 is mounted is provided at a position substantially similar to the position in the structure example in FIG. 4B.

FIG. 4D shows another structure example in which a frictional member 13 is bonded at the center of the left-side face of the ultrasonic transducer 1. In this case, approximately as in the structure examples shown in FIGS. 4B and 4C, a hole 5 for pressing and holding the ultrasonic transducer 1 is provided at the center of the ultrasonic transducer 1, namely at the node common to the primary longitudinal resonance and the secondary flexural resonance. A pin is gone through the hole 5 to press and hold the ultrasonic transducer 1.

The frictional members 13 are not limited to the arrangements shown in FIGS. 4B to 4D in the first embodiment, and they may be arranged at any position where a maximum driving force is generated in the ultrasonic transducer 1. The number of the frictional members 13 is not restricted and may be appropriately increased as in the above cases.

The structure of the automotive ultrasonic motor 20 using the ultrasonic transducer 1 of the first embodiment will now be described in detail with reference to FIGS. 6A and 6B.

The ultrasonic motor 20 of the first embodiment is constituted mainly of the ultrasonic transducer 1 having any of the structures described above, the pair of guides 21 for holding the ultrasonic transducer 1, and leaf springs 23 that are provided at both sides of the pair of the guides 21 and that urge the guides 21 in order to press the ultrasonic transducer 1 and the guides 21 with a predetermined pressure, as shown in FIGS. 6A and 6B.

The guides 21 transmit a force from pressing members (the leaf springs 23 in the first embodiment) to the ultrasonic transducer 1, and regulate the movement of the ultrasonic transducer 1 with respect to the guides 21 in a direction perpendicular to the abutting surface of the guides 21 and the ultrasonic transducer 1. Although the horizontal movement therein is also regulated by members integrated with the guides 21 in the first embodiment, it may be regulated by separate members.

Although the ultrasonic transducer 1 is regulated to move straight in the first embodiment, the ultrasonic transducer 1 may be driven along the curve when softly curved guides are provided perpendicularly, horizontally, or both perpendicularly and horizontally.

In other words, the ultrasonic motor 20 of the first embodiment is sandwiched between the two guides 21 so as to be in contact with frictional members 13, provided on opposed faces of the ultrasonic transducer 1, as shown in FIG. 6A, and serves as an automotive ultrasonic motor.

The guides 21 sandwiching the ultrasonic transducer 1 is constituted mainly of a horseshoe-shaped guide casing 21A and sliding plates 25 that are bonded to the upper and lower inner faces of the guide casing 21A, as shown in FIG. 6B.

The guide casing 21A is formed of aluminum and the sliding plates 25 are formed of zirconia ceramics.

Further, according to the first embodiment, the leaf springs 23 are provided for applying a predetermined pressure between the ultrasonic transducer 1 and the sliding plates 25. The leaf springs 23 urge the pair of the guides 21 such that one of the guides 21 is drawn to the other thereof. In other words, as shown in FIG. 6A, the leaf springs 23 have vertical spring characteristics, while they have a function of fixing members for horizontally fixing the upper and lower guides 21. In the meantime, the pressing members may be any parts that apply a force for diminishing the distance between the two guides, such as coil springs or magnets, in addition to the leaf springs. It is desirable to arrange the pressing members near both ends of the guides 21 as much as possible in order to avoid a situation where the pressure cannot be applied owing to the position of the ultrasonic transducer 1 or a situation where the pressure extremely diminishes.

The two leaf springs 23 are provided at both ends on the front face of the ultrasonic motor 20, and the two leaf springs 23 are provided at both ends on the rear face of the ultrasonic motor 20. The leaf springs 23 are fixed to the guides 21 with the corresponding screws 24, as shown in FIG. 6A.

A plurality of holes 22 for mounting and fixing are provided in the lower guide 21. The ultrasonic motor 20 is fixed to a base (not shown) with screws or the like through the holes 22. In contrast, the upper guide 21 is not fixed to a base (not shown) and is only held by the leaf springs 23.

Further, the pin 5A for transmitting the driving force is mounted in the hole 5 provided at the center of the ultrasonic transducer 1, that is, at the node common to the primary longitudinal resonance and the secondary flexural resonance (near the point where the ultrasonic transducer 1 is at a standstill in both resonant modes). Even when other resonant mode or combination of resonant modes is used, arranging the pin 5A at the node common to the resonant modes or the node of the combined mode, or at the part where a minimum resonance is excited, can transmit the driving force without inhibiting the resonance. The pin 5A serves as driving-force transmitting means for transmitting the driving force of the ultrasonic transducer 1 outside (to a driving mechanism in electronic equipment or a driven body in an apparatus) when the ultrasonic motor 20 is mounted in the electronic equipment, the apparatus, or the like.

When the ultrasonic transducer 1 is engaged with the driven body with an engaging member in the driven body, the pin 5A is not required.

In the ultrasonic motor 20 having the structure described above, by applying alternating voltage having a frequency of 160 KHz offset by π/2 phase to the A-phase and B-phase of outer electrodes of the ultrasonic transducer 1 in FIG. 6A to generate the elliptical vibration at the positions of the frictional members 13 on the ultrasonic transducer 1, it is confirmed that the ultrasonic transducer 1 itself horizontally moves.

(Advantages)

As described above, according to the first embodiment, the use of the conducting films 6 for connecting outer electrodes, in place of the lead wires for connecting the outer electrodes, in the ultrasonic transducer 1 eliminates protruding parts owing to the lead wires, thus reducing the size of the ultrasonic transducer 1. Furthermore, the protruding parts owing to the lead wires are also eliminated when the ultrasonic transducer 1 is used to constitute the ultrasonic motor 20, thus realizing the thin-shaped ultrasonic motor 20. Since the longitudinal piezoelectric effect is utilized in the first embodiment, the ultrasonic transducer 1 having a large electromechanical coupling coefficient can be realized.

The negative internal electrodes on the piezoelectric sheets 7A to 7D may be full electrodes, instead of being divided in half, in the first embodiment. In such a case, a common negative internal electrode is used.

Although the structure example of the ultrasonic motor 20 using the automotive ultrasonic transducer 1 is described in the first embodiment, the ultrasonic motor 20 is not limited to this structure. For example, it is possible to fix the ultrasonic transducer 1 to move the driven body straight. It is also possible to structure a driving ultrasonic motor 20 such that pressing a rotator, for example, serving as the driven body, toward a portion where the ultrasonic elliptical vibration is generated on the ultrasonic transducer 1 can rotate the driven body.

Although the hard material having a high mechanical quality factor (Qm) (2000) is selected as the piezoelectric element in the first embodiment, a soft material having a Qm of around 60 may be used.

### Second Embodiment

(Structure)

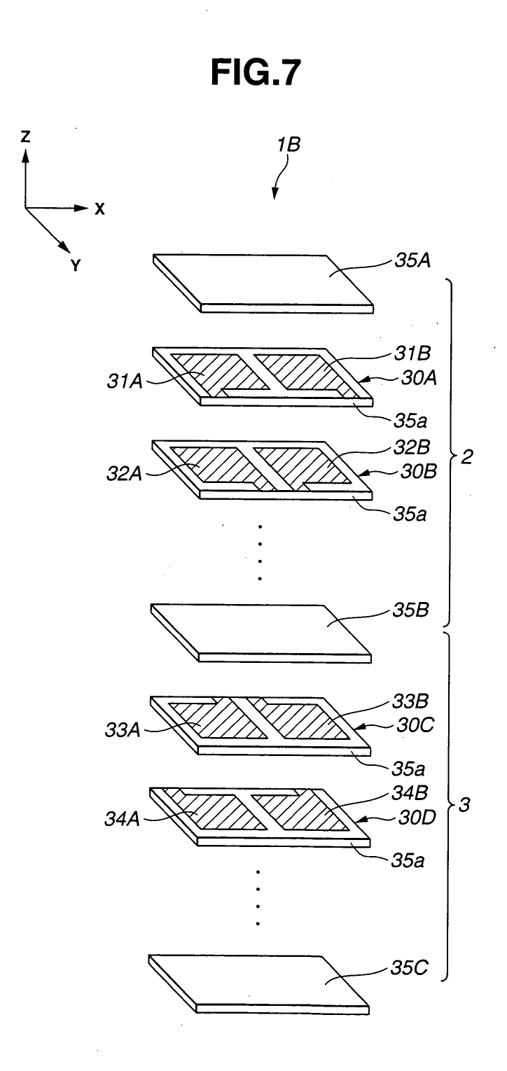

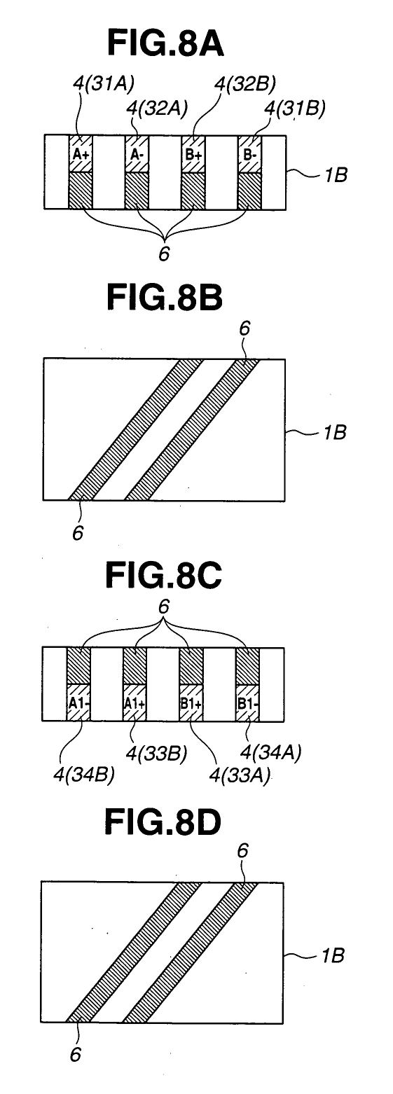

An ultrasonic transducer 1 according to a second embodiment of the present invention and an ultrasonic motor using the ultrasonic transducer 1 will now be described with reference to FIGS. 7 to 8D. FIG. 7 is an essential-part exploded perspective view showing in detail the structure of internal electrodes of the ultrasonic transducer 1 of the second embodiment. FIG. 8A to 8D schematically illustrates the configurative appearance of the ultrasonic transducer 1 mounted in the ultrasonic motor. FIG. 8A is a front view of the ultrasonic transducer 1 of the second embodiment. FIG. 8B is a top view of the ultrasonic transducer 1. FIG. 8C is a rear view of the ultrasonic transducer 1. FIG. 8D is a bottom view of the ultrasonic transducer 1. The same reference numerals are used in FIGS. 7 to 8D to identify the same components as in the ultrasonic transducer 1 of the first embodiment. The description of such components is omitted here and only the components different from those in the ultrasonic transducer 1 of the first embodiment will be described.

The ultrasonic transducer 1 of the second embodiment differs from the ultrasonic transducer 1 of the first embodiment in that piezoelectric sheets and insulative piezoelectric sheets are layered in a direction orthogonal to the longitudinal resonance (Z direction: vertical direction) to form a prismatic layered product 1B and that a manner in which outer electrodes on the front and rear face of the prismatic layered product 1B are connected by using the conducting films 6 for connecting outer electrodes.

The ultrasonic transducer 1 of the second embodiment is a layered ultrasonic transducer, as shown in FIGS. 8A to 8D, and is constituted mainly of the prismatic layered product 1B having a substantially rectangular cross section.

Referring to FIG. 7, the prismatic layered product 1B includes a first layered part 2 which is a substantially upper-half prismatic layered product, a second layered part 3 which is a substantially lower-half prismatic layered product, outer electrodes 4 provided at predetermined positions on the front face or the rear face of the first layered part 2 or the second layered part 3, and the conducting films 6 for connecting outer electrodes.

According to the second embodiment, the prismatic layered product 1B measures, for example, 10 mm width by 2.4 mm height by 4 mm depth.

The structure of internal electrodes of the ultrasonic transducer 1 of the second embodiment will now be described in detail with reference to FIG. 7. In the prismatic layered product 1B of the ultrasonic transducer 1, there are provided three insulative piezoelectric sheets 35A to 35C, which serve as insulators and are piezoelectrically inactive because of no electrode treatment. A plurality of rectangular piezoelectric sheets 30A and 30B, which are sandwiched between the insulative piezoelectric sheet 35A and the insulative piezoelectric sheet 35B to be alternately layered and undergone through internal-electrode treatment, constitute the first layered part 2; and a plurality of rectangular piezoelectric sheets 30C and 30D, which are sandwiched between the insulative piezoelectric sheet 35B and the insulative piezoelectric sheet 35C to be alternately layered and undergo internal-electrode treatment, constitutes the second layered part 3.

Specifically, alternately layering the two kinds of piezoelectric sheets 30A and 30B so as to be sandwiched between the insulative piezoelectric sheet 35A at the top of the prismatic layered product 1B and the insulative piezoelectric sheet 35B at the center of the prismatic layered product 1B constitutes the first layered part 2. Alternately layering the two kinds of piezoelectric sheets 30C and 30D so as to be sandwiched between the insulative piezoelectric sheet 35B at the center of the prismatic layered product 1B and the insulative piezoelectric sheet 35C at the bottom of the prismatic layered product 1B constitutes the second layered part 3.

The first layered part 2 has a structure in which the piezoelectric sheets 30A, each having first internal electrodes 31A and 31B formed thereon, and the piezoelectric sheets 30B, each having second internal electrodes 32A and 32B formed thereon, are alternately layered.

The second layered part 3 has a structure in which the piezoelectric sheets 30C, each having third internal electrodes 33A and 33B formed thereon, and the piezoelectric sheets 30D, each having fourth internal electrodes 34A and 34B formed thereon, are alternately layered.

In the first layered part 2, the piezoelectric sheet 30A is constituted such that the first internal electrode is divided substantially in half on a piezoelectric-sheet part 35a and so as to have areas to be connected to the outer electrodes (for an A-phase outer electrode (A+) and for a B-phase outer electrode (B+)) at the corresponding edges of the first internal electrodes 31A and 31B formed by the division.

The piezoelectric sheet 30B is formed such that the second internal electrode is divided substantially in half on a piezoelectric-sheet part 35a and so as to have areas to be connected to the outer electrodes (for an A-phase outer electrode (A−) and for a B-phase outer electrode (B−)) at the corresponding edges of the second internal electrodes 32A and 32B formed by the division.

In the second layered part 3, the piezoelectric sheet 30C is formed such that the third internal electrode is divided substantially in half on a piezoelectric-sheet part 35a and so as to have areas to be connected to the outer electrodes (for a B-phase outer electrode (B1+) and for an A-phase outer electrode (A1+)) at the corresponding edges of the third internal electrodes 33A and 33B formed by the division.

The piezoelectric sheet 30D is formed such that the fourth internal electrode is divided substantially in half on a piezoelectric-sheet part 35a and so as to have areas to be connected to the outer electrodes (for a B-phase outer electrode (B1−) and for an A-phase outer electrode (A1−)) at the corresponding edges of the fourth internal electrodes 34A and 34B formed by the division.

According to the second embodiment, the piezoelectric sheets 30A to 30D each measure, for example, 10 mm width by 4 mm depth by 50 μm thickness. The insulative piezoelectric sheets 35A and 35C each measure 10 mm width by 4 mm depth by 200 μm thickness.

According to the second embodiment, on the piezoelectric sheet 30A, the first internal electrode is divided substantially in half with an insulating gap of around 0.4 mm provided in the Y direction, constituting the first internal electrodes 31A and 31B, as shown in FIG. 7. However, as described above, the first internal electrodes 31A and 31B extend toward the proximal end of the ultrasonic transducer 1 where the first internal electrodes are in contact with the corresponding outer electrodes 4.

On the piezoelectric sheet 30B, the second internal electrode is also divided in half with an insulating gap of around 0.4 mm provided in the Y direction, constituting the second internal electrodes 32A and 32B. However, as described above, the second internal electrodes 32A and 32B extend toward the proximal end of the ultrasonic transducer 1 where the second internal electrodes are in contact with the corresponding outer electrodes 4.

On the piezoelectric sheet 30C, the third internal electrode is divided in half with an insulating gap of around 0.4 mm provided in the Y direction, constituting the third internal electrodes 33A and 33B, as shown in FIG. 7. However, as described above, the third internal electrodes 33A and 33B extend toward the decimal end of the ultrasonic transducer 1 where the third internal electrodes are in contact with the corresponding outer electrodes 4.

On the piezoelectric sheet 30D, the fourth internal electrode is also divided in half with an insulating gap of around 0.4 mm provided in the Y direction, constituting the fourth internal electrodes 34A and 34B. However, as described above, the fourth internal electrodes 34A and 34B extend toward the decimal end of the ultrasonic transducer 1 where the fourth internal electrodes are in contact with the corresponding outer electrodes 4.

The configurative appearances of the ultrasonic transducer 1 of the second embodiment will now be described in detail with reference to FIGS. 8A to 8D.

The ultrasonic transducer 1 of the second embodiment has the outer electrodes 4 at the four portions on the front face where the first internal electrodes 31A and 31B and the second internal electrodes 32A and 32B are exposed outside, as shown in FIG. 8A. The ultrasonic transducer 1 has the outer electrodes 4 at the four portions on the rear face where the third internal electrodes 33A and 33B and the fourth internal electrodes 34A and 34B are exposed outside, as shown in FIG. 8C.

The conducting films 6 for connecting outer electrodes are used to connect the outer electrodes 4 to each other in the second embodiment, as in the first embodiment.

Specifically, the A-phase outer electrode A+ is electrically connected to the A-phase outer electrode A1+ by using one conducting film 6 for connecting outer electrodes (refer to FIGS. 8A, 8B, and 8C). In this case, as shown in FIG. 8B, the conducting film 6 for connecting outer electrodes electrically connects the corresponding outer electrodes via the top face of the ultrasonic transducer 1.

The A-phase outer electrode A− is electrically connected to the A-phase outer electrode A− by using one conducting film 6 for connecting outer electrodes (refer to FIGS. 8A, 8B, and 8C).

The B-phase outer electrode B− is electrically connected to the B-phase outer electrode B− by using one conducting film 6 for connecting outer electrodes (refer to FIGS. 8A, 8C, and 8D).

The B-phase outer electrode B+ is electrically connected to the B-phase outer electrode B1+ by using one conducting film 6 for connecting outer electrodes (refer to FIGS. 8A, 8C, and 8D).

The conducting films 6 for connecting outer electrodes are provided so as to achieve such electrical connection. The practical connection state is shown in FIGS. 8A to 8D.

The manufacturing process and operation of the ultrasonic transducer 1 of the second embodiment are the same as in the first embodiment and, hence, the description of them is omitted here.

In the ultrasonic motor using the ultrasonic transducer 1 of the second embodiment, the frictional members 13 are mounted on the same positions as in the first embodiment. The structure of the ultrasonic motor using the ultrasonic transducer 1 of the second embodiment is the same as in the first embodiment and, hence, the description of it is omitted here.

(Advantages)

As described above, the ultrasonic transducer 1 of the second embodiment achieves the same advantages as in the first embodiment. In addition, since the piezoelectric sheets are layered in the direction orthogonal to the longitudinal resonance, it is difficult to separate the piezoelectric sheets of the ultrasonic transducer 1.

The negative internal electrodes on the piezoelectric sheets 30A to 30D may be full electrodes, instead of being divided in half, in the second embodiment. In such a case, a common negative internal electrode is used.

### Third Embodiment

(Structure)

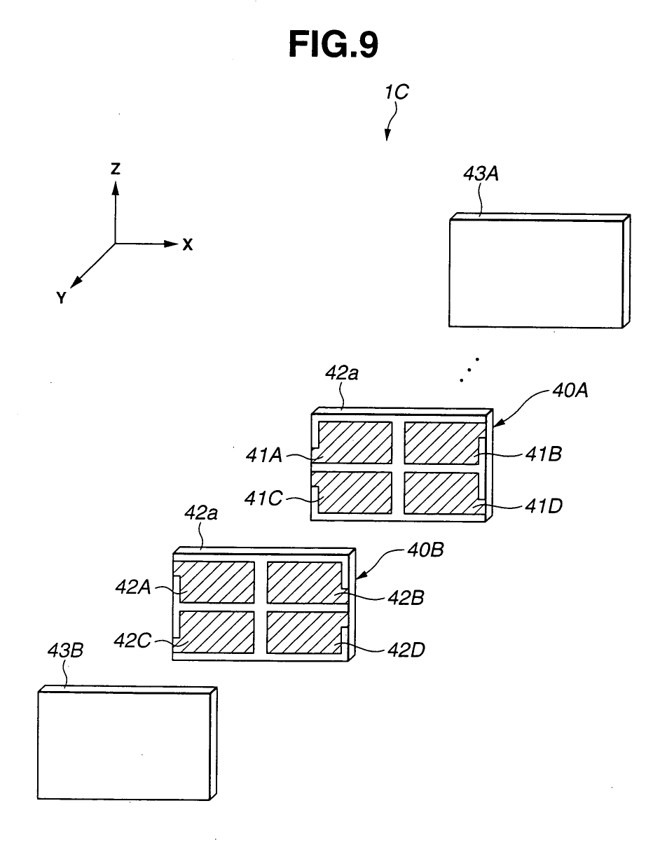

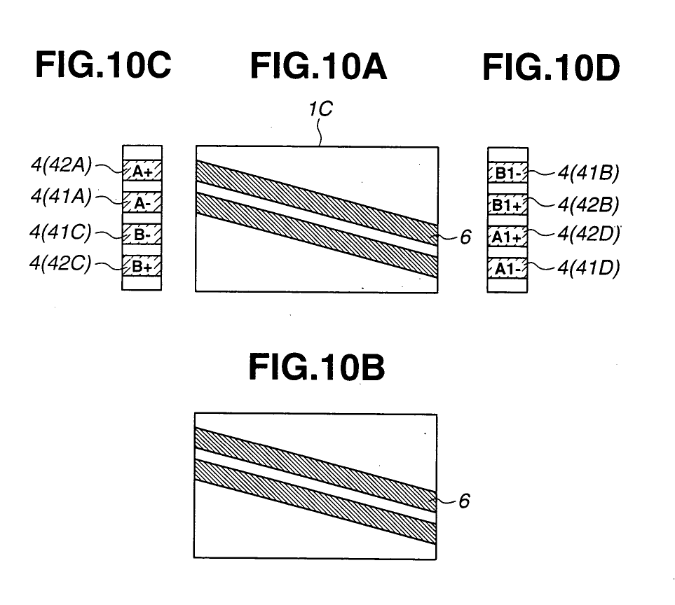

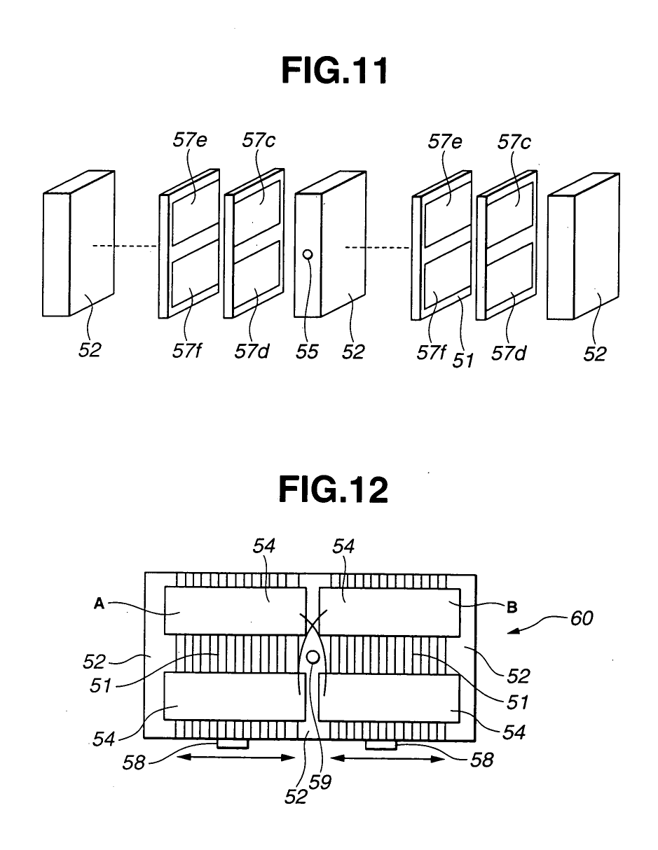

An ultrasonic transducer 1 according to a third embodiment of the present invention and an ultrasonic motor using the ultrasonic transducer 1 will now be described with reference to FIGS. 9 to 10D. FIG. 9 is an essential-part exploded perspective view showing in detail the structure of internal electrodes of the ultrasonic transducer 1 of the third embodiment. FIG. 10A to 10D schematically illustrates the configurative appearance of the ultrasonic transducer 1 mounted in the ultrasonic motor. FIG. 10A is a front view of the ultrasonic transducer 1 of the third embodiment. FIG. 10B is a rear view of the ultrasonic transducer 1. FIG. 10C is a left-side view of the ultrasonic transducer 1. FIG. 10D is a right-side view of the ultrasonic transducer 1. The same reference numerals are used in FIGS. 9 to 10D to identify the same components as in the ultrasonic transducer 1 of the first and second embodiments. The description of such components is omitted here and only the components different from those in the ultrasonic transducer 1 of the first and second embodiments will be described.

The ultrasonic transducer 1 of the third embodiment differs from the ultrasonic transducer 1 of the first embodiment in that piezoelectric sheets and insulative piezoelectric sheets are layered in a direction orthogonal to the longitudinal resonance (Y direction: direction of depth) to form a prismatic layered product 1C and that a manner in which outer electrodes on the left-side face and the right-side face of the prismatic layered product 1C are connected by using the conducting films 6 for connecting outer electrodes.

The ultrasonic transducer 1 of the third embodiment is a layered ultrasonic transducer, as shown in FIGS. 10A to 10D, and mainly includes the prismatic layered product 1C having a substantially rectangular cross section. The prismatic layered product 1C has the outer electrodes 4 (41A, 41B, 41C, 41D, 42A, 42B, 42C, and 42D) provided at predetermined position on the left-side and right-side faces thereof and the conducting films 6 for connecting outer electrodes.

The structure of internal electrodes of the ultrasonic transducer 1 of the third embodiment will now be described in detail with reference to FIG. 9. Two insulative piezoelectric sheets 43A and 43B, which serve as insulators and are piezoelectrically inactive because of no electrode treatment, and a plurality of rectangular piezoelectric sheets 40A and 40B, which are sandwiched between the insulative piezoelectric sheet 43A and the insulative piezoelectric sheet 43B to be alternately layered and undergone through internal-electrode treatment, constitute the prismatic layered product 1C of the ultrasonic transducer 1.

According to the third embodiment, the prismatic layered product 1C measures, for example, 10 mm width by 2.4 mm height by 2 mm depth.

Specifically, alternately layering the two kinds of piezoelectric sheets 40A and 40B so as to be sandwiched between the insulative piezoelectric sheet 43A at the trail of the prismatic layered product 1C and the insulative piezoelectric sheet 43B at the head of the prismatic layered product 1C constitutes the prismatic layered product 1C.

The piezoelectric sheet 40A is formed such that the first internal electrode is substantially quadrisected on a piezoelectric-sheet part 42a and so as to have areas to be connected to the outer electrodes (for A-phase outer electrodes (A− and A1−) and for B-phase outer electrodes (B− and B1−)) at the corresponding edges of the formed first internal electrodes 41A, 41B, 41C, and 41D.

The piezoelectric sheet 40B is formed such that the second internal electrode is substantially quadrisected on a piezoelectric-sheet part 42a and so as to have areas to be connected to the outer electrodes (for A-phase outer electrodes (A+ and A1+) and for B-phase outer electrodes (B+ and B1+)) at the corresponding edges of the formed second internal electrodes 42A, 42B, 42C, and 42D.

According to the third embodiment, the piezoelectric sheets 40A and 40B each measure, for example, 10 mm width by 2.4 mm height by 50 μm thickness. The insulative piezoelectric sheets 43A and 43B each measure 10 mm width by 2.4 mm height by 50 μm thickness.

According to the third embodiment, on the piezoelectric sheet 40A, the first internal electrode is practically quadrisected with an insulating gap of around 0.4 mm provided in the X direction and the Y direction to form the first internal electrodes 41A, 41B, 41C, and 41D, as shown in FIG. 9. However, as described above, the first internal electrodes 41A, 41B, 41C, and 41D extend toward the edges of the ultrasonic transducer 1 where the first internal electrodes are in contact with the corresponding outer electrodes 4.

On the piezoelectric sheet 40B, the second internal electrode is also quadrisected with an insulating gap of around 0.4 mm provided in the X direction and the Y direction to form the second internal electrodes 42A, 42B, 42C, and 42D, as shown in FIG. 9. However, as described above, the second internal electrodes 42A, 42B, 42C, and 42D extend toward the edges of the ultrasonic transducer 1 where the second internal electrodes are in contact with the corresponding outer electrodes 4.

The configurative appearances of the ultrasonic transducer 1 of the third embodiment will now be described in detail with reference to FIGS. 10A to 10D.

The ultrasonic transducer 1 of the third embodiment has the outer electrodes 4 at the four portions on the left-side face where the first internal electrodes 41A and 41C and the second internal electrodes 42A and 42C are exposed outside, as shown in FIG. 10C. The ultrasonic transducer 1 has the outer electrodes 4 at the four portions on the right-side face where the first internal electrodes 41B and 41D and the second internal electrodes 42B and 42D are exposed outside, as shown in FIG. 10D.

The conducting films 6 for connecting outer electrodes are used to connect the outer electrodes 4 to each other in the third embodiment, as in the first embodiment.

Specifically, the A-phase outer electrode A+ is electrically connected to the A-phase outer electrode A1+ by using one conducting film 6 for connecting outer electrodes (refer to FIGS. 10A, 10C, and 10D).

The A-phase outer electrode A− is also electrically connected to the A-phase outer electrode A1− by using one conducting film 6 for connecting outer electrodes (refer to FIGS. 10A, 10C, and 10D).

In these cases, as shown in FIG. 10A, the conducting films 6 for connecting outer electrodes electrically connect the corresponding outer electrodes via the front face of the ultrasonic transducer 1.

The B-phase outer electrode B− is electrically connected to the B-phase outer electrode B1− by using one conducting film 6 for connecting outer electrodes (refer to FIGS. 10B, 10C, and 10D).

The B-phase outer electrode B+ is electrically connected to the B-phase outer electrode B1+ by using one conducting film 6 for connecting outer electrodes (refer to FIGS. 10B, 10C, and 10D).

In these cases, as shown in FIG. 10B, the conducting films 6 for connecting outer electrodes electrically connect the corresponding outer electrodes via the front face of the ultrasonic transducer 1.

The manufacturing process and operation of the ultrasonic transducer 1 of the third embodiment are the same as in the first embodiment and, hence, the description of them is omitted here.

In the ultrasonic motor using the ultrasonic transducer 1 of the third embodiment, the frictional members 13 are mounted on the same positions as in the first embodiment. The structure of the ultrasonic motor using the ultrasonic transducer 1 is the same as in the first embodiment and, hence, the description of it is omitted here.

(Advantages)

As described above, the ultrasonic transducer 1 of the third embodiment achieves the same advantages as in the second embodiment.

The negative internal electrodes on the piezoelectric sheets may be full electrodes, instead of being quadrisected, in the third embodiment. In such a case, a common negative internal electrode is used.

Compared with the second embodiment, it is sufficient to provide only the two patterns for the internal electrodes, thus achieving the simplification of the manufacturing process and the reduction in the manufacturing cost.

The present invention is not limited to the first to third embodiments described above. Combination or applications of the first to third embodiments can also be applied to the present invention within the scope of the present invention.

In this invention, it is apparent that various modifications different in a wide range can be made on this basis of this invention without departing from the sprit and scope of the invention. This invention is not restricted by any specific embodiment except being limited by the appended claims.

What is claimed is:

1. An ultrasonic transducer comprising:
a first outer-electrode group and a second outer-electrode group, in which the piezoelectric elements and the internal electrodes are alternately layered respectively, and that are connected to the corresponding internal electrodes, wherein upon alternating voltage being applied to the first outer-electrode group and/or the second outer-electrode group simultaneously, a primary resonant mode and a secondary resonant mode are excited to generate ultrasonic elliptical vibration; and
conducting films for connecting outer electrodes, formed so as to be in contact with the surface of the ultrasonic transducer, for electrically connecting predetermined outer electrodes in the first outer-electrode group to predetermined outer electrodes in the second outer-electrode group.

2. The ultrasonic transducer according to claim 1, wherein a hole in which a supporting member or a member for transmitting a driving force can be mounted is formed substantially at a node common to the primary resonant mode and the secondary resonant mode.

3. The ultrasonic transducer according to claim 1, further comprising lead wires or a flexible substrate having electrodes, which is electrically connected to the conducting films for connecting outer electrodes.

4. The ultrasonic transducer according to claim 1, wherein the piezoelectric elements are formed of lead-zirconate-titanate piezoelectric ceramics.

5. The ultrasonic transducer according to claim 1, wherein the internal electrodes are formed of an alloy of silver and palladium, silver, nickel, platinum, or gold.

6. The ultrasonic transducer according to claim 1, wherein the outer electrodes and the conducting films for connecting outer electrodes are formed of silver, an alloy of silver and palladium, or platinum.

7. The ultrasonic transducer according to claim 1, further comprising frictional members bonded to positions where the ultrasonic elliptical vibration is generated.

8. The ultrasonic transducer according to claim 1, wherein the primary resonant mode is longitudinal resonance and the secondary resonant mode is flexural resonance.

9. The ultrasonic transducer according to claim 8, wherein a hole in which a supporting member or a member for transmitting a driving force can be mounted is formed substantially at a node common to the primary resonant mode and the secondary resonant mode.

10. The ultrasonic transducer according to claim 8, further comprising lead wires or a flexible substrate having electrodes, which is electrically connected to the conducting films for connecting outer electrodes.

11. The ultrasonic transducer according to claim 8, wherein the piezoelectric elements are formed of lead-zirconate-titanate piezoelectric ceramics.

12. The ultrasonic transducer according to claim 8, wherein the internal electrodes are formed of an alloy of silver and palladium, silver, nickel, platinum, or gold.

13. The ultrasonic transducer according to claim 8, wherein the outer electrodes and the conducting films for connecting outer electrodes are formed of silver, an alloy of silver and palladium, or platinum.

14. The ultrasonic transducer according to claim 8, further comprising frictional members bonded to positions where the ultrasonic elliptical vibration is generated.

15. An ultrasonic transducer comprising:
outer electrodes, in which the piezoelectric elements and the internal electrodes being alternately layered, and each being connected to the corresponding internal electrodes;
a first layered part including at least the internal electrodes, each being divided in half in a second direction orthogonal to a layering direction, which is a first direction;
a second layered part including at least the internal electrodes, each being divided in half in the second direction;
a first outer-electrode group provided so as to be connected to predetermined internal electrodes respectively in the first layered part;
a second outer-electrode group provided so as to be connected to predetermined internal electrodes respectively in the second layered part; and
conducting films for connecting outer electrodes, formed closely contacting with the surface of the ultrasonic transducer, so as to electrically connect predetermined outer electrodes in the first outer-electrode group to predetermined outer electrodes in the second outer-electrode group,
wherein upon alternating voltage being applied to the first outer-electrode group and/or the second outer-electrode group simultaneously, and a primary longitudinal resonant mode in the first direction and a secondary flexural resonant mode in a third direction orthogonal to the first direction and the second direction being excited, ultrasonic elliptical vibration is generated in the ultrasonic transducer.

16. An ultrasonic transducer comprising:
outer electrodes, in which the piezoelectric elements and the internal electrodes being alternately layered, and each being connected to the corresponding internal electrodes;
a first layered part including at least the internal electrodes, each being divided in half in a second direction orthogonal to a layering direction, which is a first direction;
a second layered part including at least the internal electrodes, each being divided in half in the second direction;
a first outer-electrode group provided so as to be connected to predetermined internal electrodes in the first layered part;
a second outer-electrode group provided so as to be connected to predetermined internal electrodes in the second layered part; and
conducting films for connecting outer electrodes, formed closely contacting with the surface of the ultrasonic transducer, so as to electrically connect predetermined outer, electrodes in the first outer-electrode group to predetermined outer electrodes in the second outer-electrode group,
wherein upon alternating voltage being applied to the first outer-electrode group and/or the second outer-electrode group simultaneously, and a primary longitudinal resonant mode in a third direction orthogonal to the first direction and the second direction and a secondary flexural resonant mode in the first direction being excited, ultrasonic elliptical vibration is generated in the ultrasonic transducer.

17. An ultrasonic transducer comprising:
outer electrodes, in which the piezoelectric elements and the internal electrodes being alternately layered, and each being connected to the corresponding internal electrodes;
an internal-electrode group, in which the piezoelectric elements and the internal electrodes being alternately layered, and each internal electrode in the internal-electrode group being substantially quadrisected in a second direction and a third direction, which are orthogonal to a layering direction, which is a first direction;
a first outer-electrode group and a second outer-electrode group, each being connected to the internal-electrode group; and
conducting films for connecting outer electrodes, formed closely contacting with the surface of the ultrasonic transducer, so as to electrically connect predetermined outer electrodes in the first outer-electrode group to predetermined outer electrodes in the second outer-electrode group,
wherein upon alternating voltage being applied to the first outer-electrode group and/or the second outer-electrode group simultaneously, and a primary longitudinal resonant mode in the second direction and a secondary flexural resonant mode in the third direction being excited, ultrasonic elliptical vibration is generated in the ultrasonic transducer.

18. An ultrasonic motor comprising at least:
the ultrasonic transducer according to claim 1;
a driven body that moves with respect to the ultrasonic transducer; and
a pressing member for pressing the ultrasonic transducer toward the driven body.

19. An ultrasonic motor according to claim 18, wherein the driven body moves straight.

20. An ultrasonic motor according to claim 18, wherein the driven body rotates.
